(19) United States
(12) Patent Application Publication
(10) Pub. No.: US 2014/0111183 A1
(43) Pub. Date: Apr. 24, 2014

(54) APPARATUS AND METHOD FOR MEASURING POWER COMSUMPTION BY USING SENSING TAG

(71) Applicant: ELECTRONICS AND TELECOMMUNICATIONS RESEARCH INSTITUTE, Daejeon (KR)

(72) Inventors: SungIk JUN, Daejeon (KR); Baik Song AN, Daejeon (KR); Byeong Thaek OH, Daejeon (KR); Young Choon WOO, Daejeon (KR); Wan CHOI, Daejeon (KR)

(73) Assignee: ELECTRONICS AND TELECOMMUNICATIONS RESEARCH INSTITUTE, Daejeon (KR)

(21) Appl. No.: 14/059,032

(22) Filed: Oct. 21, 2013

(30) Foreign Application Priority Data
Oct. 19, 2012 (KR) 10-2012-0116774
Oct. 14, 2013 (KR) 10-2013-0122204

(51) Int. Cl. G01R 21/00

(52) U.S. Cl. CPC G01R 21/00
USPC 324/76.11

(57) ABSTRACT

An apparatus and method for measuring power using a sensing tag are provided. The power measuring apparatus includes a power sensing tag and a power measurement control system. The power sensing tag is installed in a line along which power is supplied to a load of a target device, and measures power consumed by the load. The power measurement control system receives power information measured by the power sensing tag from the power sensing tag, and determines power consumed by the load by using the measured power information.

### CROSS-REFERENCE TO RELATED APPLICATION

This application claims priority to and the benefit of Korean Patent Application No. 10-2012-0116774 and No. 10-2013-0122204 filed in the Korean Intellectual Property Office on Oct. 19, 2012, and Oct. 14, 2013, respectively, the entire contents of which are incorporated herein by reference.

### BACKGROUND OF THE INVENTION

(a) Field of the Invention

The present invention relates to an apparatus and method for measuring power consumption using a sensing tag.

(b) Description of the Related Art

An increase in energy consumption of IT devices leads to the necessity of power saving techniques, and a power measuring apparatus for accurately measuring power use of each IT device should be installed. In order to apply a power saving technique, a method for accurately measuring power use should come first. This is because, unless electric power used by each load of an IT device is accurately measured, it is very difficult to determine which part should be improved.

Conventionally, in order to measure power use, high-priced additional equipment such as a power meters has been used. A power meter is installed in a location in which overall electric power is supplied, and overall power use is measured by the power meter. However, the biggest problem is that in order to measure electric power consumption of each load of an IT device, a power meter must be installed in each device, causing problems by increased costs. Furthermore, the system board of an IT device should be revised as well. Another problem of using an exclusive power meter for each load is that total the power meter itself consumes power, which causes extra power overheads.

Meanwhile, in previous work, measured power obtained from a power meter is transferred via wire communication. In case of multiple measurements, additional complicated circuits and wiring must be installed.

### SUMMARY OF THE INVENTION

The present invention has been made in an effort to provide an apparatus and method for measuring power consumption using a sensing tag that can easily measure power consumption of each load of an IT device.

An exemplary embodiment of the present invention provides a power measuring apparatus for measuring power consumption of a target device. The power measuring apparatus may include: a first power sensing tag installed in a first line along which power is supplied to at least one first load among a plurality of loads of the target device, and configured to measure power supplied to the first load; and a power measurement control system configured to receive first power measurement information measured by the first power sensing tag from the first power sensing tag, and determine power consumed by the first load by using the first power measurement information.

The power measuring apparatus may further include a second power sensing tag installed in a second line along which power is supplied to the entirety of the target device and configured to measure overall power supplied to the target device.

The power measurement control system may receive second power measurement information measured by the second power sensing tag from the second power sensing tag, and calculate power efficiency of the target device by using the second power measurement information and the first power measurement information.

The first power sensing tag may measure the first power measurement information through a resistor connected to the first line.

The second power sensing tag may be installed in a front stage of a power supply unit that supplies power input from the outside of the target device to the target device.

The first power sensing tag may measure the first power measurement information periodically.

The first power sensing tag may transmit and receive a signal to and from the power measurement control system wirelessly.

The target device may be at least one of a computer system, a storage system and a network system. Or, it may be a computing component such as HDD, SDD, NIC, and memory module.

The power measurement control system may include: a power monitoring unit configured to determine power consumed by the first load by using the first power measurement information; a tag controller configured to manage the first power sensing tag; and a tag reader configured to transmit or receive a signal to or from the first power sensing tag.

The first power measurement information may correspond to a value of the current supplied to the first load.

Another embodiment of the present invention provides a power sensing tag. The power sensing tag may include: a measurement unit configured to measure power supplied to at least one of a plurality of loads of a target device; an analog-to-digital conversion unit configured to convert the measured power into a digital signal; a controller configured to store the measured power in a memory; and a wireless transceiver unit configured to transmit the measured power to the outside wirelessly.

The measurement unit may measure power through a resistor connected to the line along which power is supplied to the at least one load.

The controller may store the measured power in the memory periodically.

The power sensing tag may further include a switch positioned between the controller and the wireless transceiver unit, wherein the controller may control the switch such that the measured power is transmitted to the outside wirelessly.

Yet another embodiment of the present invention provides a power measuring method for measuring power consumption of a target device. The power measuring method may include: providing a first power sensing tag installed in at least one first load among a plurality of loads of the target device; receiving first power measurement information measured by the first power sensing tag from the first power sensing tag; and determining power consumed by the first load by using the first power measurement information.

The power measuring method may further include: providing a second power sensing tag installed in a line along which power is supplied to the entirety of the target device; receiving second power measurement information measured by the second power sensing tag from the second power sensing tag;

and calculating power efficiency of the target device by using the second power measurement information and the first power measurement information.

The first power sensing tag may measure the first power measurement information periodically.

According to an embodiment of the present invention, power use of a corresponding each component load of electric device can be simply measured by using a power sensing tag installed in each load of an IT device.

### BRIEF DESCRIPTION OF THE DRAWINGS

FIG. 1 is a view illustrating an apparatus for measuring power consumption (or a power measuring apparatus) 100 and a target device 200 whose power consumption is to be measured by the power measuring apparatus 100 according to an embodiment of the present invention.

FIG. 2 is a view illustrating a method of connecting a second power sensing tag 110b_1 to a CPU 230 as a load according to an embodiment of the present invention.

FIG. 3 is a view illustrating a method for measuring power consumption by the power measuring apparatus 100 according to an embodiment of the present invention.

FIG. 4 is a view illustrating a specific configuration of a power sensing tag 110 according to an embodiment of the present invention.

FIG. 5 is a view illustrating a specific configuration of a power measurement control system 120 according to an embodiment of the present invention.

### DETAILED DESCRIPTION OF THE EMBODIMENTS

In the following detailed description, only certain exemplary embodiments of the present invention have been shown and described, simply by way of illustration. As those skilled in the art would realize, the described embodiments may be modified in various different ways, all without departing from the spirit or scope of the present invention. Accordingly, the drawings and description are to be regarded as illustrative in nature and not restrictive. Like reference numerals designate like elements throughout the specification.

Throughout the specification, unless explicitly described to the contrary, the word “comprise” and variations such as “comprises” or “comprising” will be understood to imply the inclusion of stated elements but not the exclusion of any other elements.

Also, throughout this specification and the claims that follow, when it is described that an element is “coupled” to another element, the element may be “directly coupled” to the other element or “electrically coupled” to the other element through a third element.

Hereinafter, an apparatus and method for measuring power consumption using a sensing tag according to an embodiment of the present invention will be described in detail with reference to the accompanying drawings.

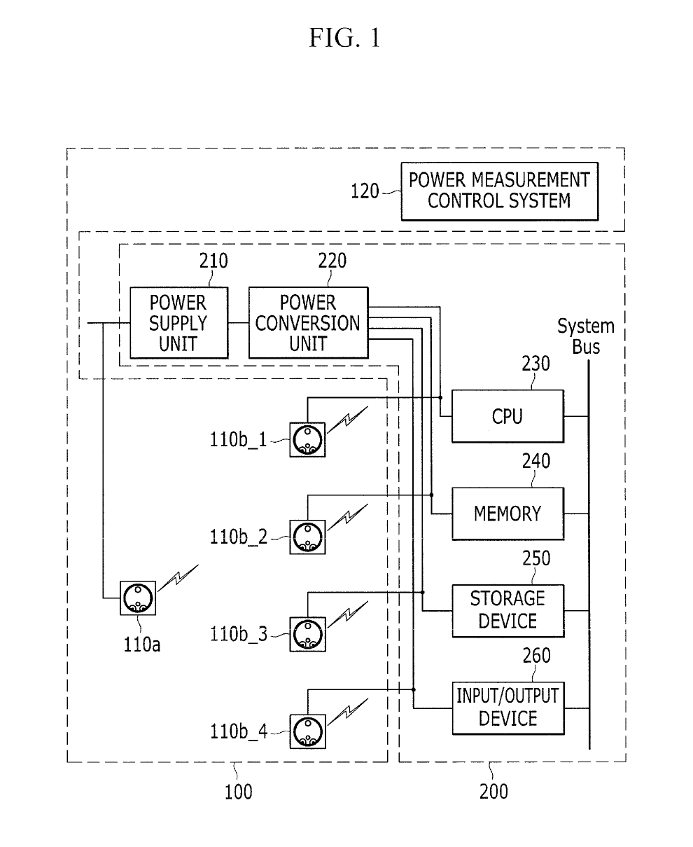

First, an apparatus for measuring power consumption using a sensing tag according to an embodiment of the present invention will be described with reference to FIG. 1.

FIG. 1 is a view illustrating an apparatus for measuring power consumption (or a power measuring apparatus) 100 and a target device 200 whose power consumption is to be measured by the power measuring apparatus 100 according to an embodiment of the present invention.

As illustrated in FIG. 1, the power measuring apparatus 100 according to an embodiment of the present invention includes a first power sensing tag 110a, a plurality of second power sensing tags 110b_1 to 110b_4, and a power measurement control system 120.

In FIG. 1, the computer system 200 is illustrated as a target whose power consumption is to be measured by the power measuring apparatus 100, but it is natural that it may be changed another electric device, for example storage device, network device, etc.

The computer system 200 includes a power supply unit 210, a power conversion unit 220, a CPU 230, a memory 240, a storage device 250, and an input/output device 260.

The power supply unit 210 is a device supplying power input from the outside to the computer system 200 overall, and the power conversion unit 220 converts power supplied from the power supply unit 210 into power with which respective loads 230, 240, 250, and 260 are operable. In FIG. 1, the respective loads of the computer system 200 are illustrated as the CPU 230, the memory 240, the storage device 250, and the input/output device 260, but it is natural that the loads may be changed or a load may be added.

The first power sensing tag 110a is connected to an inlet at the front stage of the power supply unit 210, and measures overall power supplied to the computer system 200. In other words, the first power sensing tag 110a is connected to the inlet power line in which overall power of the computer system 200 is supplied, to measure overall power consumption.

The plurality of second power sensing tags 110b_1 to 110b_4 measure power supplied to the loads 230, 240, 250, and 260, respectively. The second power sensing tag 110b_1 is connected to a power line along which power is supplied to the CPU 230, to measure power supplied to the CPU 230. The second power sensing tag 110b_2 is connected to a line along which power is supplied to the memory 240, to measure power supplied to the memory 240. The second power sensing tag 110b_3 is connected to a line along which power is supplied to the storage device 250, and the second power sensing tag 110b_4 is connected to a line along which power is supplied to the input/output device 260.

The first power sensing tag 110a and the plurality of second power sensing tags 110b_1 to 110b_4 transmit the measured power consumption to the power measurement control system 120 according to a command from the power measurement control system 120, respectively.

The power sensing tags 110a to 110b_4 are simply implemented as ultra-low-power-type tags, so installation of the tags in each load does not incur much cost.

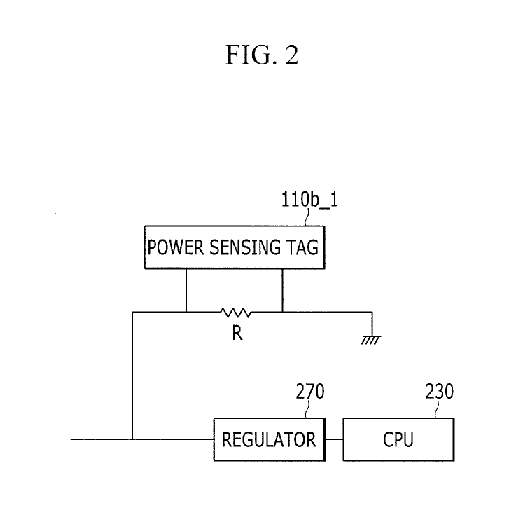

FIG. 2 is a view illustrating a method of connecting a second power sensing tag 110b_1 to a CPU 230 as a load according to an embodiment of the present invention. In FIG. 2, the method of connecting the second power sensing tag 110b_1 to a load is illustrated, but the other power sensing tags 110a an 110b_2 to 110b_4 may also be connected to each load in the same manner.

In general, in order to stably supply power to the CPU 230 as a load, a regulator 270 is installed.

The second power sensing tag 110b_1 may be installed in an input power line of the regulator 270. When the regulator 270 is not present in a front stage of a load, the second power sensing tag 110b_1 may be installed in an input power line of the CPU 230 through which power is supplied to the CPU 230.

As illustrated in FIG. 2, a sensing shunt resistor R is connected between an input power line of the regulator 270 and a ground, and the second power sensing tag 100b_1 is connected to both ends of the sensing shunt resistor R. The sensing shunt resistor R may be included as a component of the second power sensing tag 110b_1.

The second power sensing tag 110b_1 may measure a voltage across the sensing shunt resistor R, and calculates a current supplied to the CPU 230 by using the measured voltage and of current consumption of the sensing shunt resistor R. The value of the current calculated by the second power sensing tag 110b_1 is information regarding power supplied to the CPU 230.

The second power sensing tag 110b_1 converts the calculated power value into a digital signal and periodically stores the converted digital signal in the memory, and the stored current measurement information is wirelessly transmitted to the power measurement control system 120 according to a request from the power measurement control system 120.

Hereinafter, the current measurement information measured by the power sensing tags 110a to 110b_4 will be used interchangeably with “power measurement information”.

The power measurement control system 120 communicates with the power sensing tags 110a to 110b_4 through a contactless wireless interface, and manages and controls the power sensing tags 110a to 110b_4 overall. The power measurement control system 120 determines power consumed in each load by analyzing the power measurement information transmitted from the plurality of second power sensing tags 110b_1 to 110b_4. The power measurement control system 120 may calculate power efficiency of the computer system 200 by using the power measurement information transmitted from the first sensing tag 110a and the power measurement information transmitted from the plurality of second power sensing tags 110b_1 to 110b_4. The power measurement information transmitted from the first power sensing tag 110a is information regarding overall power supplied to the computer system 200, and the power measurement information transmitted from the plurality of second power sensing tags 110b_1 to 110b_4 is information regarding power supplied to the respective loads 230 to 260 of the computer system 200. Thus, the power measurement control system 120 may calculate power efficiency of the computer system 200 by converting a value obtained by subtracting the power measurement information transmitted from the plurality of second power sensing tags 110b_1 to 110b_4 from the power measurement information transmitted from the first power sensing tag 110a into a percentage.

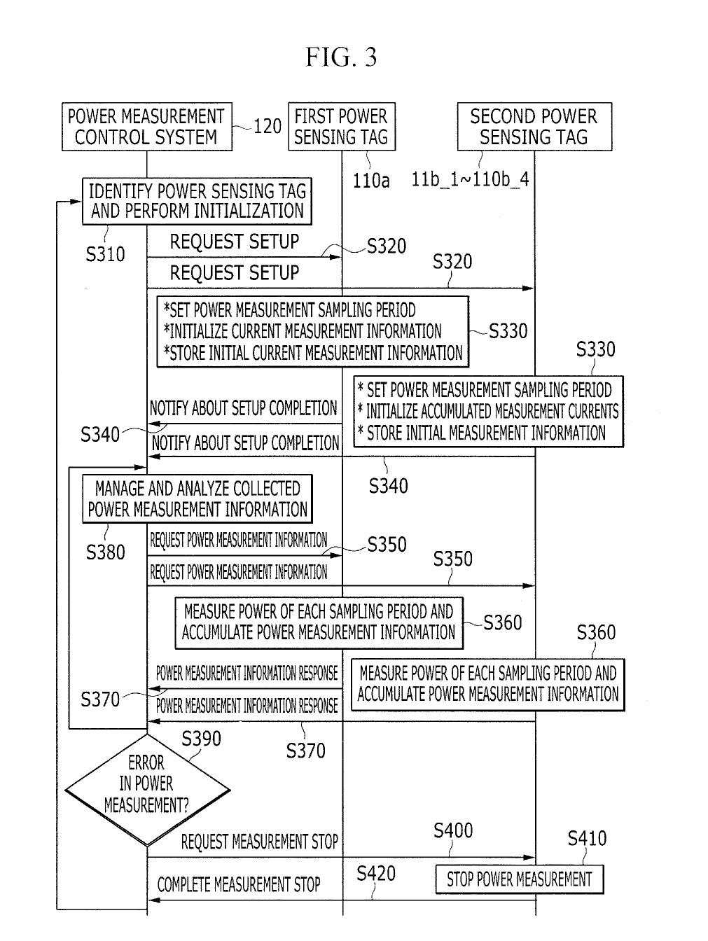

Hereinafter, a method for measuring power consumption according to an embodiment of the present invention will be described with reference to FIG. 3.

FIG. 3 is a view illustrating a method for measuring power consumption by the power measuring apparatus 100 according to an embodiment of the present invention.

First, the power measurement control system 120 identifies the power sensing tags 110a to 110b_4 installed in the computer system 200 to recognize the information regarding the managed power sensing tags 110a to 110b_4 (S310). The power measurement control system 120 initializes the information regarding the identified power sensing tags 110a to 110b_4 (for example, information regarding a changed amount of power sensing tags) (S310).

Thereafter, the power measurement control system 120 transmits a setup request message to the first power sensing tag 110a and the second power sensing tags 110b_1 to 110b_4 (S320).

Upon receiving the setup request message from the power measurement control system 120, the first power sensing tag 110a and the second power sensing tags 110b_1 to 110b_4 set a sampling period for power measurement (S330). The sampling period may be included in the setup request message. The first power sensing tag 110a and the second power sensing tags 110b_1 to 110b_4 initialize the current measurement information (i.e., the power measurement information) stored in the memory (S330). That is, the first power sensing tag 110a and the second power sensing tags 110b_1 to 110b_4 initialize the current measurement information stored in the memory. Meanwhile, the first power sensing tag 110a and the second power sensing tags 110b_1 to 110b_4 store current measurement information (initial current measurement information) first measured after the initialization of the current measurement information in the memory (S330).

Next, the first power sensing tag 110a and the second power sensing tags 110b_1 to 110b_4 transmit a setup complete message to the power measurement control system 120 (S340).

Upon receiving the setup complete message, the power measurement control system 120 requests power measurement information from the first power sensing tag 110a and the second power sensing tags 110b_1 to 110b_4 (S350). A message requesting the power measurement information may include read and update commands.

The first power sensing tag 110a and the second power sensing tags 110b_1 to 110b_4 measure power at every sampling period, and accumulate power measurement information in the memory (S360).

The first power sensing tag 110a and the second power sensing tags 110b_1 to 110b_4 transmit the accumulated power measurement information to the power measurement control system 120 (S370).

The power measurement control system 120 manages and analyzes the power measurement information collected from the first power sensing tag 110a and the second power sensing tags 110b_1 to 110b_4 (S380). The power measurement control system 120 may determine in which of the loads power is greatly consumed by using the collected power measurement information. The power measurement control system 120 may calculate power efficiency of the computer system 200 by using the power measurement information transmitted from the first power sensing tag 110a and the power measurement information transmitted from the plurality of second power sensing tags 110b_1 to 110b_4.

The operations S350, S360, S370, and S380 may be repeatedly performed at every management period of the power measurement control system 120.

Meanwhile, when there is an error in the results data obtained by analyzing the power measurement information collected from the first power sensing tag 110a and the second power sensing tags 110b_1 to 110b_4 (S390), the power measurement control system 120 transmits a measurement stop request message to the second power sensing tags 110b_1 to 110b_4 having an error (S400). For example, a data error may occur when any one of pieces of power measurement information transmitted from the second power sensing tags 110b_1 to 110b_4 is excessively greater than an existing value. In such a case, a corresponding power sensing tag has a problem.

Upon receiving the measurement stop request message from the power measurement control system 120, the second power sensing tags 110b_1 to 1101b_4 stop power measurement (S410).

The second power sensing tags 110b_1 to 110b_4, which has stopped power measurement, transmits a measurement stop complete message to the power measurement control system 120.

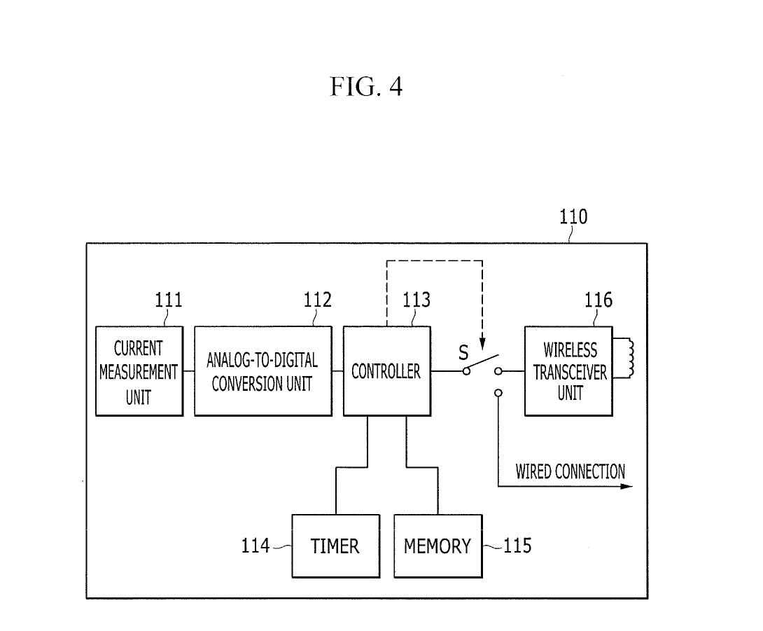

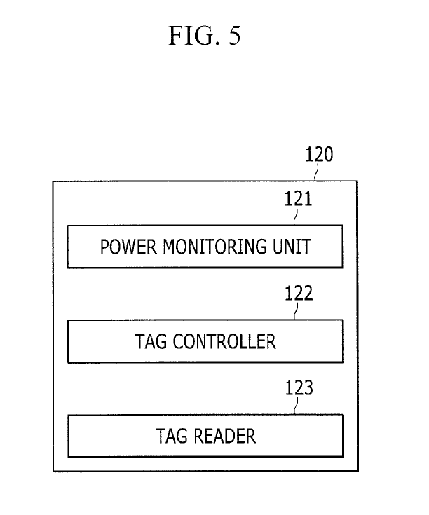

Hereinafter, a configuration of the power sensing tags 110a to 110b_4 and that of the power measurement control system 120 according to an embodiment of the present invention will be described with reference to FIGS. 4 and 5.

FIG. 4 is a view illustrating a specific configuration of the power sensing tag 110 according to an embodiment of the present invention. The power sensing tags 110a to 110b_4 according to an embodiment of the present invention as described above may have a configuration of the power sensing tag 110 as illustrated in FIG. 4.

As illustrated in FIG. 4, the power sensing tag 110 according to an embodiment of the present invention includes a current measurement unit 111, an analog-to-digital conversion unit 112, a controller 113, a timer 114, a memory 115, and a wireless transceiver unit 116.

The current measurement unit 111 measures a current supplied to a load (e.g., the CPU 230). The current measurement unit 111 measures a voltage across the sensing shunt resistor R as described above with reference to FIG. 2, and calculates a current by using the measured voltage and the sensing shunt resistor R value. Of course, any method other than the method of measuring a current by using the sensing shunt resistor R may also be applicable.

The analog-to-digital conversion unit 112 receives the current measurement information measured by the current measurement unit 111, and converts the current measurement information as an analog signal into a digital signal. The method of converting the analog signal into a digital signal may be easily known by a person skilled in the art to which the present invention pertains, so a detailed description thereof will be omitted.

The controller 113 stores the current measurement information converted by the analog-to-digital conversion unit 112 in the memory 115 according to a sampling period. When there is a power measurement information request from the power measurement control system 120, the controller 113 transmits the current measurement information stored in the memory 115 to the power measurement control system 120 via the wireless transceiver unit 116. Meanwhile, the controller 113, which controls an overall operation of the power sensing tag 110 such as initialization of the power sensing tag 110, or the like, may be implemented through simple logic.

The timer 114 provides time information to the controller 113, and the controller 113 stores the current measurement information in the memory 115 according to the sampling period by using the time information provided from the timer 114.

In order to wirelessly transmit the current measurement information to the power measurement control system 120, the wireless transceiver unit 116 modulates the current measurement information according to a predetermined communication standard, and transmits the modulated signal to the power measurement control system 120. The wireless transceiver unit 116 demodulates a signal transmitted from the power measurement control system 120, and delivers the demodulated signal to the controller 113.

Meanwhile, a switch S may be positioned between the controller 113 and the wireless transceiver unit 116, and the controller 113 controls the switch S. For wireless communication between the power sensing tag 110 and the power measurement control system 120, the controller 113 controls the switch S so that the controller 113 may be connected to the wireless transceiver unit 116. In case of wired communication between the power sensing tag 110 and the power measurement control system 120, the controller 113 may control the switch S such that the controller is connected in a wired manner (or through a fixed line).

FIG. 5 is a view illustrating a specific configuration of the power measurement control system 120 according to an embodiment of the present invention.

As illustrated in FIG. 5, the power measurement control system 120 according to an embodiment of the present invention includes a power monitoring unit 121, a tag controller 122, and a tag reader 123.

The power monitoring unit 121 monitors and analyzes power consumed in each load by using the power measurement information transmitted from the power sensing tags 110a to 110b_4. The power monitoring unit 121 may calculate power efficiency of the computer system 200 by using the power measurement information transmitted from the first power sensing tag 110a and the power measurement information transmitted from the plurality of second power sensing tags 110b_1 to 110b_4.

The tag controller 122 serves to manage the power sensing tags 110a to 110b_4, such as initialization of the power sensing tags 110a to 110b_4, or the like.

The tag reader 123 serves to transmit or receive a signal to or from the power sensing tags 110a to 110b_4. As illustrated in FIG. 5, the tag reader 123 may be installed within the power measurement control system 120 or may be installed in the form of a USB in the computer system 200. When the tag reader 123 is installed in the form of a USB in the computer system 200, the tag reader 123 may transmit a signal received from the power sensing tags 110a to 110b_4 to the power measurement control system 120, and may transmit a signal received from the power measurement control system 120 to the power sensing tags 110a to 110b_4.

While this invention has been described in connection with what is presently considered to be practical exemplary embodiments, it is to be understood that the invention is not limited to the disclosed embodiments, but, on the contrary, is intended to cover various modifications and equivalent arrangements included within the spirit and scope of the appended claims.

What is claimed is:

1. A power measuring apparatus for measuring power consumption of a target device, the apparatus comprising:
a first power sensing tag installed in a first line along which power is supplied to at least one first load among a plurality of loads of the target device, and configured to measure power supplied to the first load; and
a power measurement control system configured to receive first power measurement information measured by the first power sensing tag from the first power sensing tag, and determine power consumed by the first load by using the first power measurement information.

2. The power measuring apparatus of claim 1, further comprising
a second power sensing tag installed in a second line along which power is supplied to the entirety of the target device, and configured to measure overall power supplied to the target device.

3. The power measuring apparatus of claim 2, wherein the power measurement control system receives second power measurement information measured by the second power sensing tag from the second power sensing tag, and calculates power efficiency of the target device by using the second power measurement information and the first power measurement information.

4. The power measuring apparatus of claim 1, wherein the first power sensing tag measures the first power measurement information through a resistor connected to the first line.

5. The power measuring apparatus of claim 2, wherein the second power sensing tag is installed in a front stage of a power supply unit that supplies power input from the outside of the target device to the target device.

6. The power measuring apparatus of claim 1, wherein the first power sensing tag measures the first power measurement information periodically.

7. The power measuring apparatus of claim 1, wherein the first power sensing tag transmits and receives a signal to and from the power measurement control system wirelessly.

8. The power measuring apparatus of claim 1, wherein the target device is at least one of a computer system, a storage system and a network system.

9. The power measuring apparatus of claim 1, wherein the power measurement control system comprises:
a power monitoring unit configured to determine power consumed by the first load by using the first power measurement information;
a tag controller configured to manage the first power sensing tag; and
a tag reader configured to transmit or receive a signal to or from the first power sensing tag.

10. The power measuring apparatus of claim 1, wherein the first power measurement information corresponds to a value of the current supplied to the first load.

11. A power sensing tag comprising:
a measurement unit configured to measure power supplied to at least one of a plurality of loads of a target device;
an analog-to-digital conversion unit configured to convert the measured power into a digital signal;
a controller configured to store the measured power in a memory; and
a wireless transceiver unit configured to transmit the measured power to the outside wirelessly.

12. The power sensing tag of claim 11, wherein the measurement unit measures power through a resistor connected to the line along which power is supplied to the at least one load.

13. The power sensing tag of claim 11, wherein the controller stores the measured power in the memory periodically.

14. The power sensing tag of claim 11, wherein
the power sensing tag further comprises a switch positioned between the controller and the wireless transceiver unit,
wherein the controller controls the switch such that the measured power is transmitted to the outside wirelessly.

15. A power measuring method for measuring power consumption of a target device, the method comprising:
providing a first power sensing tag installed in at least one first load among a plurality of loads of the target device;
receiving first power measurement information measured by the first power sensing tag from the first power sensing tag; and
determining power consumed by the first load by using the first power measurement information.

16. The method of claim 15, further comprising:
providing a second power sensing tag installed in a line along which power is supplied to the entirety of the target device;
receiving second power measurement information measured by the second power sensing tag from the second power sensing tag; and
calculating power efficiency of the target device by using the second power measurement information and the first power measurement information.

17. The method of claim 15, wherein the first power sensing tag measures the first power measurement information periodically.
